(19) United States
(12) Patent Application Publication
(10) Pub. No.: US 2014/0105511 A1
(43) Pub. Date: Apr. 17, 2014

(54) MATCHED REPRESENTATION SPACE METHOD FOR NUMERICALLY ENCODING DATA

(71) Applicant: MacAulay-Brown, Inc., Dayton, OH (US)

(72) Inventors: John A. Kosinski, Wall Township, NJ (US); Richard V. Burns, Beavercreek, OH (US); Elliott J. Moser, Dayton, OH (US); Richard J. Kozick, Danville, PA (US); Steve R. Lindle, Beavercreek, OH (US); Nicholas A. Pequignot, Dayton, OH (US)

(73) Assignee: MacAulay-Brown, Inc., Dayton, OH (US)

(21) Appl. No.: 14/051,095

(22) Filed: Oct. 10, 2013

Related U.S. Application Data
(60) Provisional application No. 61/712,641, filed on Oct. 11, 2012.

(51) Int. Cl. H03M 7/30; G06T 9/00

(52) U.S. Cl. CPC H03M 7/3059; G06T 9/001
USPC 382/232; 341/51

(57) ABSTRACT

According to one embodiment, the present invention includes a method for numerically encoding and representing data that includes providing a representation of data and separating the representation into a scale header and an additional precision packet. Separating the representation includes identifying the location of the highest-order non-zero bit and encoding the location of the highest-order non-zero bit to form the scale header. The balance of the bits following the highest-order non-zero bit, or a truncated set of these bits, is encoded to form the additional precision packet, and a matched representation space (MRS) representation is composed of the paired data structures of a scale header and a corresponding additional precision packet, if any.

### CLAIM OF PRIORITY

This application claims priority to U.S. Provisional Patent Application No. 61/712,641, filed Oct. 11, 2012, the disclosure of which is hereby incorporated by reference herein.

### FIELD OF THE INVENTION

The present invention relates to the field of data representation and has applications in data compression, transmission, and storage. More specifically, the invention provides a new method for numerically encoding data that is directly applicable to the encoding of numerical data and indirectly applicable to the encoding of any and all other data, provided that the data symbols or characters are translated to an equivalent set of numerical codes.

### BACKGROUND OF THE INVENTION

The Matched Representation Space (MRS) method of data representation and thinning is a method that came out of efforts to overcome limitations in the Alternative Bases Processing (ABP) method of data compression and signal processing. The ABP method centers on the use of a non-orthogonal transformation intended to provide dimensionality reduction while maintaining full signal energy through the compression process. Detailed analysis of the ABP process identified issues arising from the introduction of unintended distortions and errors by the non-orthogonal transform. The discovery and invention of MRS is a direct result of considering the basic properties of image data while in search of ways to mitigate the distortions and errors within ABP. Specifically, we began to consider questions on the accuracy and precision required to reproduce a data set to a specified finite error, or a specified finite relative error. Simply put, distortions and errors are not necessarily a problem as long as they are smaller than the precision (absolute or relative) that the data are rounded to. We thus began considering the fundamental properties of signals, signal data, their representation as numerical and binary data, and their properties as they are manipulated by image, signal, and data processing steps. The key concepts that came together to produce MRS are those of significant and non-significant digits, and the binary series representation of integer data.

The prior art in the representation of numerical data is best understood through the example of binary data. Consider the N-bit binary representation of an integer I. The N-bits bₙ are the coefficients of the binary power series representation of that integer I:

I=Σₙ₌₀^{N-1}bₙ2ⁿ (1)

The binary power series is an exact representation of the integer I as indicated by the equal sign in equation (1), and this is a significant piece of implicit a priori information underlying conventional digital data representation, storage, transmission, and processing. The fact that the lower limit of the series is zero and that the base for the power series is two constitute implicit a priori knowledge in any use of a binary integer representation. There is no implicit upper limit on the power series, thus the number of bits N corresponding to the number of terms in the series is required as explicit a priori information. The coefficients can be gathered as bits into a binary “word” as a sequence of N total ones and zeros, typically in an order following the powers of the expansion. The bit sequence is typically ordered from high to low in accordance with the norms of positional notation. Thus the left-most bit in the word corresponds to the coefficient of the highest-order term in the expansion, and the right-most bit corresponds to the coefficient of the lowest-order term in the expansion. These two bits are commonly referred to as the “most significant bit” (msb) and the “least significant bit” (lsb) respectively based on their positional significance in the representation scheme; however this common usage violates the definition of the term significant figures which is defined by Merriam Webster Dictionary as “figures of a number that begin with the first figure to the left that is not zero and that end with the last figure to the right that is not zero or is a zero that is considered to be correct.”

The common usage of the “most significant bit” and “least significant bit” terminology embodies a significant technical error that has placed a conceptual barrier on the prior art. The prior art has required the use of a fixed length binary data field with the explicit transmission of a binary character for every element in the data field without regard to significance and whether the element is actually a non-significant place-holder.

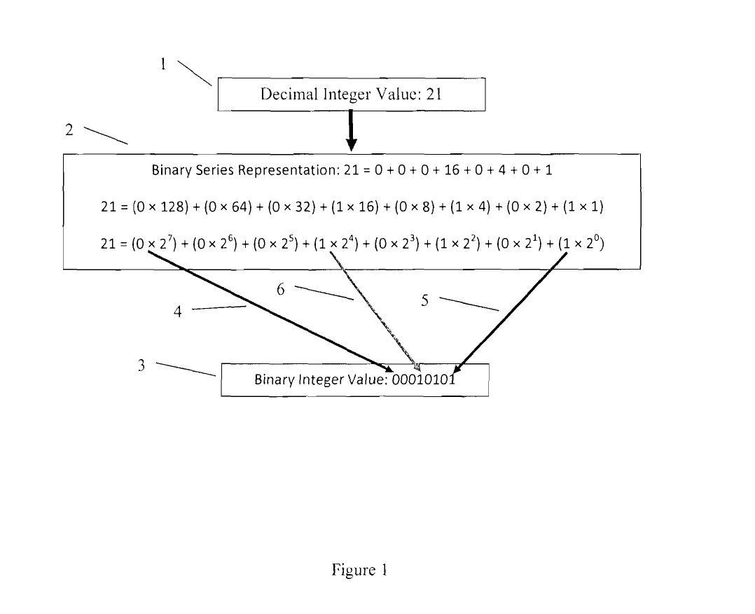

Referring now to FIG. 1, consider a decimal number encoded as a standard binary integer. The process begins with the original decimal number (here, we use the number “21” as an example) labeled as item 1 in FIG. 1. Mathematically, the decimal number may be expanded in a binary power series, in this particular example as

21=16+4+1=2⁴+2²+2⁰ (2)

The binary series expansion is shown as item 2 in FIG. 1. In the conventional binary word structure, the bits in the binary word represent the coefficients of the binary series expansion in order from the highest-order term to the lowest order term. The conventional binary word is shown as item 3 in FIG. 1. The commonly understood “most significant bit” is the left-most bit in the binary word, while the “least significant bit” is the right-most bit in the binary word. In reality, the commonly denoted “most significant bit” is actually the “highest-order bit” as shown by arrow 4 marking the direct linkage of the coefficient of the highest-order term in the expansion to the left-most bit. Similarly, the commonly denoted “least significant bit” is actually the “lowest-order bit” as shown by arrow 5 marking the direct linkage of the coefficient of the lowest-order term in the expansion to the right-most bit. As will be discussed further, the actual most significant bit is the highest-order non-zero bit and its location in the series and linkage to the binary word are shown by the arrow 6. For the example of decimal integer 21, the corresponding N=8 bit conventional binary word is encoded as 00010101, in which the three leading zeros are non-significant and function simply as place-holders. It is important to note that the conventional binary word is a single, inseparable data structure whose interpretation is based upon the one-to-one ordered correspondence between the bits in the binary word and the coefficients in the binary series expansion.

Addressing the conceptual error associated with the common usage of the “most significant bit” and “least significant bit” terminology has been the key to unlocking a new and improved data representation. The new method as disclosed here overcomes these disadvantages and limitations by properly recognizing significance, thus leading to an improved data structure that separates the numerical data into a scale header and an additional precision packet. The scale header and additional precision packet form separate and separable data structures in the MRS method that are represented differently, can be stored and transmitted independently, and processed independently or jointly.

### SUMMARY OF THE INVENTION

Accordingly, the present invention provides a new method for numerically encoding data. The Matched Representation Space (MRS) method is based upon the concept of significant figures and separates the representation into a scale header and an additional precision packet. The new method provides options for both exact and approximate data representations that afford advantages in data compression, transmission, and storage.

According to one embodiment, the present invention includes a method for representing and numerically encoding data that includes providing a representation of data and separating the representation into a scale header and an additional precision packet. Separating the representation includes identifying the location of the highest-order non-zero bit and encoding the location of the highest-order non-zero bit to form the scale header. The balance of the bits following the highest-order non-zero bit, or a truncated set of these bits, is encoded to form the precision packet.

The scale header and additional precision packet form separate and separable data structures in the MRS method that are represented differently, can be stored and transmitted independently, and processed independently or jointly.

Other objects, advantages and salient features of the invention will become apparent from the following detailed description, which, taken in conjunction with the annexed drawing, discloses a preferred embodiment of the present invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying FIGS. 1-3.

### DETAILED DESCRIPTION OF THE INVENTION

The disadvantages of the prior art can be overcome by using a new method for forming the data representation that separates the numerical data into a scale header and an additional precision packet. The new method provides options for both exact and approximate data representations that afford advantages in data compression, transmission, and storage as will be made clear in the description that follows and as illustrated in the Figures.

The new method centers on the concept of significant figures, and this is directly related to the concepts of accuracy and precision:

Merriam: Definition of ACCURACY
“1: freedom from mistake or error: CORRECTNESS
2a: conformity to truth or to a standard model: EXACTNESS
2b: degree of conformity of a measure to a standard or a true value—compare PRECISION
2a”

Merriam: Definition of PRECISION
“1: the quality or state of being precise: EXACTNESS
2a: the degree of refinement with which an operation is performed or a measurement stated—compare ACCURACY 2b
2b: the accuracy (as in binary or decimal places) with which a number can be represented usually expressed in terms of the number of computer words available for representation <double precision arithmetic permits the representation of an expression by two computer words>”

We take accuracy as defined by correctness and precision as defined by exactness for consistency with the definition of significant figures. The significant figures correctly represent a datum at the corresponding level of precision, i.e., every figure that is significant is deemed to be accurate. The MRS representation conceptually divides the data representation into accuracy (scale) and precision components, and assures that the representation is correct to within definable level of exactness. A scale header represents the correct value of the “most significant bit” where a “significant bit” is defined as bits of a binary number that begin with the first bit to the left that is not zero and that end with the last bit to the right that is considered to be correct.

In the MRS representation scheme, we recognize that any leading zeros in the binary word are placeholders and are not significant figures in a scientific or technical usage of the data. We also recognize that smaller figures to the right are non-significant when they cannot be considered accurate. The partition into a scale header and an additional precision packet allows for a simple means to accurately represent the data to within a stated level of precision, and to add successively higher precision if required. This partition reflects a fundamental difference in the meaning and interpretation of binary and other numerical data represented using the MRS method. Whereas a conventional binary word communicates a mathematical equality as defined by Eq. (1), corresponding MRS data structures communicate a bounded region of uncertainty where the uncertainty has a maximum possible value and can be reduced to zero by adding precision. Mathematically, for any integer with true value β represented using the MRS method and binary symbols, the simplest MRS representation μ is established solely by the scale header and bounds the true value β from below as

μ≦β<2μ (2)

The uncertainty range is reduced by one half for every additional bit of precision encoded in the additional precision packet, up until the point that the MRS representation forms an exact representation of the true value with zero uncertainty. Thus, whereas a conventional binary word only communicates an exact value, an MRS data structure communicates both an exact lower bound to a possible value (via the scale header) and a specified uncertainty range (via the size of the additional precision packet). The representation of exact values using MRS is limited only by the number of symbols encoded in the additional precision packet.

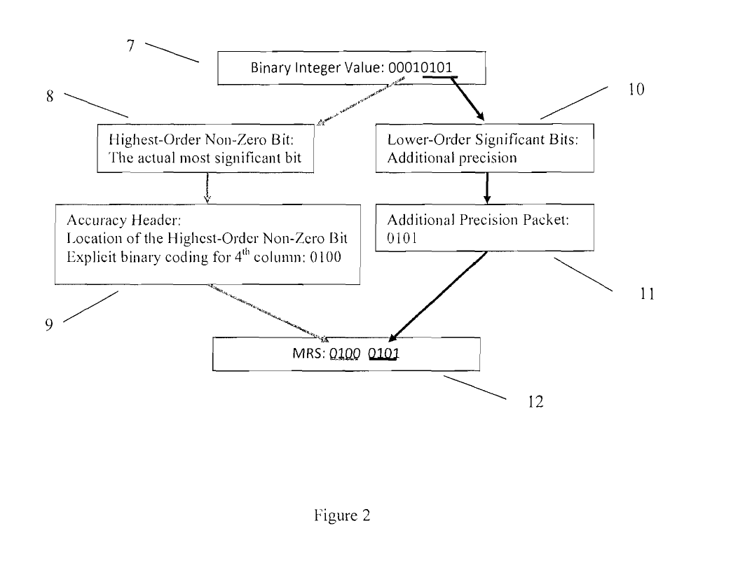

Referring now to FIG. 2, we illustrate the MRS representation of the same number “21” as used in the earlier example of a conventional binary integer. For the purposes of illustration, we begin with the N=8-bit binary integer representation of “21” labeled as item 7 in FIG. 2, noting that the method can be implemented just as readily from the original decimal integer. In the case considered here, we first identify the location of the highest-order non-zero bit, which is the actual most significant bit. This step is labeled as 8 in FIG. 2. We then encode the location of that bit as a scale header in the step labeled as 9 in FIG. 2, noting that there are several possible schemes for the encoding (coding the total number of significant elements, coding the number of leading zeros, coding the location as number of columns from the left in an N-bit format, etc.). The specific coding method is not critical, but must be made available to any subsequent decoding steps. In this specific example, we use a scheme based on coding the location as the number of columns from the left in an N-bit word. Thus the scale header is encoded as the four symbol sequence 0100 corresponding to the binary representation of the integer 4, with the explicit understanding that the symbol in the fourth column is a “1.” The balance of the binary sequence that follows the highest-order non-zero bit represents additional precision in the binary representation, and this set of bits is labeled as 10 in FIG. 2. This set of bits, or a truncated set of these bits, form the additional precision packet labeled as 11 in FIG. 2. In this example there are 4 additional bits of precision represented by the symbol sequence 0101. The Matched Representation Space binary representation is labeled as 12 in FIG. 2, and this is composed of the separable and separate scale header 9 and additional precision packet 11. In contrast to the conventional binary word that embodies a single, inseparable data structure, the separate scale header 9 and additional precision packet 11 data structures are distinct and do not have a shared interpretation as coefficients in the binary series expansion. For any case of more than a single datum, the scale headers 9 and additional precision packets 11 for the multiple data elements can be stored or transmitted on an interleaved basis, datum by datum, or as separate scale header 9 and additional precision packet 11 arrays. In fact, there are substantial advantages to storing, transmitting, and processing the scale header on its own as a separate array.

For binary integers, the accuracy of the MRS representation is guaranteed for even the smallest possible representation by the encoding of the most significant bit. For binary integers, the smallest possible MRS representation will always be within a factor of two of the true value as bounded from below, and this is significantly better than the simplest conventional decimal approximation that would capture the correct decimal order of magnitude. The MRS additional precision packet improves the exactness of the representation with each additional precision bit, with the maximum potential MRS representation error decreasing by one half for each additional bit, as bounded from below. Note that the rate at which precision improves is constant over all of the significant bits in the MRS binary representation.

Preferred and Alternate Embodiments: The MRS method can be implemented in a number of ways depending upon the specific requirements of the application. Four options are available with respect to using fixed or variable length data structures, and whether the data are represented at full precision or at some designated lesser precision:

1) Full precision MRS representation with fixed length data structures. This option balances certain advantages in the MRS representation scheme against a fractional increase in the size of the representation when maintaining absolute fidelity to the binary truth data. This option increases the total number of symbols used to represent the data as compared to simply using the original binary truth data, as shown in Table I. Inflation occurs in this scheme since the data structure length is sized to accommodate the largest possible scale header and the largest possible precision packet at the same time, whereas these occur as opposites in the truth data (i.e., a binary word with no leading zeros has N precision bits; a binary word with all leading zeros requires no precision bits; for any case in between the sum of the leading zeros and precision bits totals to the N-bit length of the conventional binary word). Note, however, that this inflation occurs prior to any entropy encoding, and that the entropy encoding can be expected to recover some or all of that inflation.

TABLE I
Number of Symbols Required to Represent a Conventional N-bit
Binary Integer Using Full Precision MRS with Fixed Length Data Structures.

| | | MRS | | MRS Data Structure |
|---|---|---|---|---|
| Conventional | MRS Scale | Additional | | Size Relative to |
| Binary Word | Header | Precision | MRS Data Structure | Conventional Binary |
| Length (bits) | (symbols) | (symbols) | Length (symbols) | Word Length |
| 4 | 3 | 3 | 6 | 1.50 |
| 8 | 4 | 7 | 11 | 1.38 |
| 16 | 5 | 15 | 20 | 1.25 |
| 32 | 6 | 31 | 37 | 1.16 |
| 64 | 7 | 64 | 71 | 1.11 |
| 128 | 8 | 127 | 135 | 1.06 |
| 256 | 9 | 255 | 264 | 1.03 |
| 512 | 10 | 511 | 521 | 1.02 |
| 1024 | 11 | 1023 | 1034 | 1.01 |
| N | ┌log₂(N + 1)┐ | N − 1 | N + ┌log₂(N + 1)┐ − 1 | $1 + \frac{⌈ {log}_{2} ( N + 1 ) ⌉}{N} - \frac{1}{N}$ |

In the example of an N=8 bit binary integer given here, the scale header 0100 and additional bits of precision represented by the symbol sequence 0101 would be padded with three additional trailing zeros to fill out the field of seven total additional precision bits yielding a full precision MRS fixed length data structure composed of the scale header 0100 and the additional precision packet 0101000 with a total size of eleven symbols.

2) Full precision MRS representation with variable length data structures. The number of scale header bits is explicit a priori information that also establishes the number of additional bits of precision following the scale header, and this makes the use of variable length data structures simple to implement. The use of variable length data structures can be expected to change the size of the representation, and also impacts on the approaches available for entropy encoding. The size of the MRS data may be increased, decreased, or use the same number of symbols to represent the data depending on the particular integer(s) being represented. The longest full precision variable length MRS binary representations are equal in size to the corresponding full precision fixed length MRS binary words. Thus when considering any data set composed of multiple data elements, the increase in MRS binary representation size as shown in Table I also establishes the upper limit on the increase in size of the data representation when using full precision variable length MRS binary representations. The smallest full precision variable length MRS binary representations are those that encode all zeros. These are analyzed in Table II for the same cases as considered in Table I. Taken together, Tables I and II bound the possible range of expansion or compression that can be achieved for an arbitrary set of conventional binary words when converted to full precision MRS representation with variable length data structures. Depending on the size (in number of bits N) and distribution of the conventional binary words, substantial lossless compression is at least theoretically possible.

In the example of an N=8 bit binary integer given here, the scale header 0100 and additional bits of precision represented by the symbol sequence 0101 would be represented as-is without padding any additional trailing zeros, thus yielding a full precision MRS variable length data structure of scale header 0100 and additional precision packet 0101 with an overall data structure length of eight symbols.

TABLE II
Smallest Number of Symbols Required to Represent a Conventional
N-bit Binary Integer Using MRS with Variable Length Data Structures.

| | | | | MRS Binary |
|---|---|---|---|---|
| | | | | Data Structure |
| | MRS | MRS | MRS Data | Size Relative |
| Conventional | Scale | Additional | Structure | to Conventional |
| Binary Word | Header | Precision | Length | Binary |
| Length (bits) | (symbols) | (symbols) | (symbols) | Word Length |
| 4 | 3 | 0 | 3 | 0.75 |
| 8 | 4 | 0 | 4 | 0.50 |
| 16 | 5 | 0 | 5 | 0.31 |
| 32 | 6 | 0 | 6 | 0.19 |
| 64 | 7 | 0 | 7 | 0.11 |
| 128 | 8 | 0 | 8 | 0.06 |
| 256 | 9 | 0 | 9 | 0.04 |
| 512 | 10 | 0 | 10 | 0.02 |
| 1024 | 11 | 0 | 11 | 0.01 |
| N | ┌log₂(N + 1)┐ | 0 | ┌log₂(N + 1)┐ | $\frac{⌈ {log}_{2} ( N + 1 ) ⌉}{N}$ |

3) Adjusted precision MRS with fixed length data structures. This option involves an explicit size for the fixed data structure resulting in an implicit size for the precision packet, or an explicit size of the precision packet resulting in an implicit size of the data structure. In either case, the size of the precision packet defines the limiting relative precision of the data representation.

The smallest possible fixed length representation is simply the scale header. The scale header bounds the true data value from below, and is always within a factor of two of the full precision true data value. The precision packet is padded with trailing zeros as needed when the size of the precision packet exceeds the size of the true precision data available. Each additional precision bit reduces by one half the maximum possible representation errors, up to the point that the data are represented at full precision. As with the scale header, the true data are bounded from below in the MRS representation. We observe that in appending additional precision bits, the MRS representation refines each data element at the same rate of increasing relative precision, up to the point that full precision is reached for that data element or the maximum data structure length is reached.

We designate the order of the precision P as the number of symbols in the original data sequence that are coded exactly in the MRS(P) representation. Clearly, the upper limit is P=N meaning that every bit in the N-bit conventional word is represented exactly using MRS(P=N). Since the header encodes the location of the highest-order non-zero bit, this is designated as MRS(1). Appending one precision bit yields MRS(2), appending two precision bits yields MRS(3), etc. In the example of an N=8 bit binary integer given here, the scale header 0100 constitutes the complete MRS(1) data structure of a fixed four symbol length. The MRS(2) representation would expand the data structure to include an additional precision packet composed of the next precision bit for a data structure of scale header 0100 and additional precision packet 0 for a fixed five symbol length. The MRS(3) representation would append another precision bit to the additional precision packet a for a data structure of scale header 0100 and additional precision packet 01, etc. Finally, the MRS(8) representation that would guarantee full precision in representing the data would pad trailing zeros yielding the data structure of scale header 0100 and additional precision packet 0101000 for a fixed eleven symbol length. The characteristics of several cases of interest are shown in Tables III-VI.

TABLE III
Number of Symbols Required to Represent a Conventional 8-bit Binary Integer
Using MRS(P) with M-Symbol Fixed Length Data Structures for Selected Cases.

| | | MRS(P) | MRS(P) | | MRS(P) Binary Data |
|---|---|---|---|---|---|
| Conventional | | Scale | Additional | MRS(P) Data | Structure Size Relative |
| Binary Word | MRS(P) | Header | Precision | Structure Length | to Conventional Binary |
| Length (bits) | Precision | (symbols) | (symbols) | M (symbols) | Word Length |
| 8 | 1 | 4 | 0 | 4 | 0.50 |
| 8 | 2 | 4 | 1 | 5 | 0.63 |
| 8 | 3 | 4 | 2 | 6 | 0.75 |
| 8 | 4 | 4 | 3 | 7 | 0.88 |
| 8 | 5 | 4 | 4 | 8 | 1.00 |
| N | P | ┌log₂(N + 1)┐ | P − 1 | ┌log₂(N + 1)┐ + P − 1 | $\frac{⌈ {log}_{2} ( N + 1 ) ⌉}{N} + \frac{P - 1}{N}$ |

TABLE IV
Number of Symbols Required to Represent a Conventional 16-bit Binary Integer
Using MRS(P) with M-Symbol Fixed Length Data Structures for Selected Cases.

| | | MRS(P) | MRS(P) | | MRS(P) Binary Data |
|---|---|---|---|---|---|
| Conventional | | Scale | Additional | MRS(P) Data | Structure Size Relative |
| Binary Word | MRS(P) | Header | Precision | Structure Length | to Conventional Binary |
| Length (bits) | Precision | (symbols) | (symbols) | M (symbols) | Word Length |
| 16 | 1 | 5 | 0 | 5 | 0.31 |
| 16 | 2 | 5 | 1 | 6 | 0.38 |
| 16 | 3 | 5 | 2 | 7 | 0.44 |
| 16 | 4 | 5 | 3 | 8 | 0.50 |
| 16 | 5 | 5 | 4 | 9 | 0.56 |
| 16 | 6 | 5 | 5 | 10 | 0.63 |
| 16 | 7 | 5 | 6 | 11 | 0.69 |
| 16 | 8 | 5 | 7 | 12 | 0.75 |
| 16 | 9 | 5 | 8 | 13 | 0.81 |
| 16 | 10 | 5 | 9 | 14 | 0.88 |
| 16 | 11 | 5 | 10 | 15 | 0.94 |
| 16 | 12 | 5 | 11 | 16 | 1.00 |
| N | P | ┌log₂(N + 1)┐ | P − 1 | ┌log₂(N + 1)┐ + P − 1 | $\frac{⌈ {log}_{2} ( N + 1 ) ⌉}{N} + \frac{P - 1}{N}$ |

TABLE V
Number of Symbols Required to Represent a Conventional 32-bit Binary Integer
Using MRS(P) with M-Symbol Fixed Length Data Structures for Selected Cases.

| | | MRS(P) | MRS(P) | | MRS(P) Binary Data |
|---|---|---|---|---|---|
| Conventional | | Scale | Additional | MRS(P) Data | Structure Size Relative |
| Binary Word | MRS(P) | Header | Precision | Structure Length | to Conventional Binary |
| Length (bits) | Precision | (symbols) | (symbols) | M (symbols) | Word Length |
| 32 | 1 | 6 | 0 | 6 | 0.19 |
| 32 | 2 | 6 | 1 | 7 | 0.22 |
| 32 | 3 | 6 | 2 | 8 | 0.25 |
| 32 | 4 | 6 | 3 | 9 | 0.28 |
| 32 | 5 | 6 | 4 | 10 | 0.31 |
| 32 | 6 | 6 | 5 | 11 | 0.34 |
| 32 | 7 | 6 | 6 | 12 | 0.38 |
| 32 | 8 | 6 | 7 | 13 | 0.41 |
| 32 | 9 | 6 | 8 | 14 | 0.44 |
| 32 | 10 | 6 | 9 | 15 | 0.47 |
| 32 | 11 | 6 | 10 | 16 | 0.50 |
| 32 | 27 | 6 | 26 | 32 | 1.00 |
| N | P | ┌log₂(N + 1)┐ | P − 1 | ┌log₂(N + 1)┐ + P − 1 | $\frac{⌈ {log}_{2} ( N + 1 ) ⌉}{N} + \frac{P - 1}{N}$ |

TABLE VI
Number of Symbols Required to Represent a Conventional 64-bit Binary Integer
Using MRS(P) with M-Symbol Fixed Length Data Structures for Selected Cases.

| | | MRS(P) | MRS(P) | | MRS(P) Binary Data |
|---|---|---|---|---|---|
| Conventional | | Scale | Additional | MRS(P) Data | Structure Size Relative |
| Binary Word | MRS(P) | Header | Precision | Structure Length | to Conventional Binary |
| Length (bits) | Precision | (symbols) | (symbols) | M (symbols) | Word Length |
| 64 | 1 | 7 | 0 | 7 | 0.11 |
| 64 | 2 | 7 | 1 | 8 | 0.13 |
| 64 | 3 | 7 | 2 | 9 | 0.14 |
| 64 | 4 | 7 | 3 | 10 | 0.16 |
| 64 | 5 | 7 | 4 | 11 | 0.17 |
| 64 | 6 | 7 | 5 | 12 | 0.19 |
| 64 | 7 | 7 | 6 | 13 | 0.20 |
| 64 | 8 | 7 | 7 | 14 | 0.22 |
| 64 | 9 | 7 | 8 | 15 | 0.23 |
| 64 | 10 | 7 | 9 | 16 | 0.25 |
| 64 | 11 | 7 | 10 | 32 | 0.50 |
| 64 | 27 | 7 | 26 | 64 | 1.00 |
| N | P | ┌log₂(N + 1)┐ | P − 1 | ┌log₂(N + 1)┐ + P − 1 | $\frac{⌈ {log}_{2} ( N + 1 ) ⌉}{N} + \frac{P - 1}{N}$ |

4) Adjusted precision MRS with variable length data structures. The number of scale header bits is explicit a priori information that also establishes the number of available additional bits of precision following the scale header. Depending upon the nature of the data being considered, there may be reason to truncate the precision packet according to some rule set established as explicit a priori information regarding the representation scheme. This option has properties similar to those of using variable length data structures with full precision as regards the size of the representation depending upon the size(s) of the data to be represented, and that the size of the MRS data may be increased, decreased, or use the same number of symbols to represent the data. Under any rule set, the longest possible adjusted precision variable length MRS binary representations are equal in size to the corresponding full precision variable length MRS binary words, thus Table I also establishes the upper limit on the increase in size of the data representation when using adjusted precision variable length MRS binary data structures. The smallest adjusted precision variable length MRS binary representations are those that encode only the scale header as MRS(1). The limiting cases of adjusted precision with variable length data structures for common conventional binary word sizes are summarized in Table VII. Taken together, Tables I and VII bound the possible range of expansion or compression that can be achieved for an arbitrary set of conventional binary words when converted to full precision MRS representation with variable length data structures. Depending on the size (in number of bits N) and distribution of the conventional binary words, substantial lossless compression is at least theoretically possible.

TABLE VII
Lower Bound on the Number of Symbols Required to Represent a
Conventional N-bit Binary Integer Using Adjusted Precision MRS with
Variable Length Data Structures for Selected Cases.

| | | | | Minimum | MRS(P) Variable |
|---|---|---|---|---|---|
| | | | MRS(P) | Variable Data | Binary Data |
| Conventional | Equivalent | Scale | Additional | Structure | Structure Size Relative |
| Binary Word | MRS(P) | Header | Precision | Length | to Conventional |
| Length (bits) | Precision | (symbols) | (symbols) | M (symbols) | Binary Word Length |
| 4 | 1 | 3 | 0 | 3 | 0.75 |
| 8 | 1 | 4 | 0 | 4 | 0.50 |
| 16 | 1 | 5 | 0 | 5 | 0.31 |
| 32 | 1 | 6 | 0 | 6 | 0.19 |
| 64 | 1 | 7 | 0 | 7 | 0.11 |
| 128 | 1 | 8 | 0 | 8 | 0.06 |
| 256 | 1 | 9 | 0 | 9 | 0.04 |
| 512 | 1 | 10 | 0 | 10 | 0.02 |
| 1024 | 1 | 11 | 0 | 11 | 0.01 |
| N | P | ┌log₂(N + 1)┐ | 0 | ┌log₂(N + 1)┐ | $\frac{⌈ {log}_{2} ( N + 1 ) ⌉}{N}$ |

In the example of an N=8 bit binary integer given here, the scale header 0100 constitutes the smallest possible adjusted precision variable length data structure, composed solely of the scale header 0100. Similarly, the scale header 0100 and corresponding full additional precision packet 0101 forms the largest possible adjusted precision variable length data structure.

Additional Implementation Considerations: All four implementation options encumber several additional considerations.

1) Scale Header—The scale header needs to encode the position of the highest-order non-zero bit within the N-bit binary sequence, within a scheme that can accommodate values as large as N and also accommodate the case of no non-zero bits. Thus there are N+1 cases that need to be encoded. The minimum length for the MRS representation is then the number of bits required to fully encode the header as

Minimum MRS word length=┌log₂ (N +1)┐ (2)

where ┌ ┐ denotes the ceiling function, i.e., the smallest integer larger than the argument of the function.

The fact that there are actually N+1 possible cases for the location of the highest-order non-zero bit in the conventional binary word leads to inefficient coding for the most common cases where N itself is an integer power of the base two (N=4, 8, 16, 32, 64, etc.). As an engineering expedient in reducing the size of the representation, the N+1 cases can be reduced to N cases through several schemes, such as by encoding the number of leading zeros, and treating the two possible cases of N−1 leading zeros as a single special case. Alternatively, the N+1 cases can be reduced to N cases by unambiguously interpreting the cases that specify the location of the highest-order non-zero bit up to the N−1 position, and ambiguously interpreting a ‘1’ in the N position as a special case. Both of these schemes involve ambiguity in the least significant bit that can be resolved explicitly by an additional precision packet composed of a single precision bit. As an alternative, the value of the least significant bit can be interpolated on a statistical basis.

2) Interpolation—The MRS representation scheme provides straightforward means to track which of the MRS symbols are an exact representation of the conventional binary data, and which are otherwise. Significantly, the MRS representation bounds the true data from below to within an interval defined by the step size of the lowest-order exactly represented bit. This is a very desirable property in that it allows interpolation of the next one or two smaller bits, if desired at point of use, as a statistical approach to reducing the representation error.

The MRS method distinguishes those symbols that represent ‘true’ values from those that do not. The smallest ‘true’ value is the least significant reported bit, which is not necessarily the least significant bit overall as some thinned precision (less than full precision) may be in use. Depending upon the nature of the data, adjusted precision combined with interpolation may provide a means for ‘statistically lossless’ compression, where the data recovered after compression have the same mean and variance as the full precision true data, although individual data elements may differ from their corresponding full precision true values. The ‘statistically lossless’ option is desirable as a means for achieving greater compression where the data are intended for processes whose outputs depend on the statistics of the data set, as compared to processes whose outputs depend on specific element by element values. The MRS method allows for three options in handling the representation.

a) Assign zero to all symbols beyond the least significant reported bit. This option maintains the MRS representation as a lower bound to the full precision value. For uniformly distributed data, the average representation error is approximately the size of the least significant reported bit.

b) Assign one to all symbols beyond the least significant reported bit. This option maintains the MRS representation as an upper bound to the full precision value. For uniformly distributed data, the average representation error in this case is also approximately the size of the least significant reported bit.

c) Interpolate the next smaller bit following the least significant reported bit. The interpolation can be done blindly or based on an analysis of the statistics of the next smaller bit.

i.) In the blind case, the statistics of the data are unknown. This option assigns a symbol one to the next smaller bit and a symbol zero to any further smaller bits. The advantage in doing so is that, for uniformly distributed data, the average representation error is reduced to approximately one half the size of the least significant reported bit. The disadvantage in doing so is that the interpolated value represents a statistical mean value and not a crisp lower or upper bound to the full precision value.

ii.) If the statistics of the data are known, then the representation errors can be minimized by interpolating using a longer sequence of symbols corresponding to the mean value of the smaller symbols.

3) Entropy Encoding—The sequence of symbols used in the MRS representation can be packed more compactly using any entropy encoding scheme. For arrays of data, the MRS representations can be encoded directly by serial encoding of the symbol stream, or indirectly using a bit-plane approach. The MRS representation is fully compatible with standard entropy encoding techniques such as arithmetic coding, run length coding, and L-Z or L-Z-W coding. The details of the entropy encoding will vary depending upon the nature of the original data and the type of MRS representation being used. Some example cases are as follows:

a) Using fixed length MRS methods to represent an array of numerical data. The entropy encoding can be applied serially on an element by element basis. The scale header data and additional precision packet data can be encoded as two distinct structures, or on an interleaved basis as a larger meta-structure. Similarly, the scale header data and additional precision packet data can be encoded as two distinct structures, packed in parallel by decomposing the data arrays into a series of bit planes, or on an interleaved bit-plane basis as a larger meta-structure. A two dimensional array of numbers can be thought of as defining a three dimensional surface with the magnitudes of the numbers indicating the height of the surface above the coordinate plane of the array. In this sense, the MRS scale header bit planes encode the most significant components of that surface. Each subsequent additional precision bit plane then encodes an increased precision in the accuracy and exactness of the representation of the surface. The MRS data structure left aligns all of the additional precision bits and right pads any non-significant bits as zeros. In the bit plane decomposition, that results in each plane adding precision at the same rate for all data elements, until the limiting precision of any particular data element is reached. That also results in the sparseness of the higher-order conventional bit planes being transferred to the lower additional precision packet bit planes in the fixed length MRS representation. Under those conditions, entropy coding, data storage, and data transmission are likely to be more efficient when performed on a bit plane basis.

b) Using variable length MRS methods to represent an array of numerical data. Variable length MRS employs a fixed length scale header and a corresponding variable length additional precision packet. The variable length makes bit plane representation of the additional precision packets difficult. The scale header can be encoded as bit planes, and then the additional precision packets can be encoded serially on an element by element basis.

Known techniques for data compression include a variety of transforms on and component decompositions of arrays of data represented as matrices. There is no apparent fundamental incompatibility between MRS and the use of transforms and other techniques as applied to data compression. However, there may be practical issues that will lead to a preferred order of operations when joining MRS with other techniques.

### Useful Properties of the Invention

Several properties of the Matched Representation Space method of data representation bear additional consideration.

1) Generality of the Matched Representation Space (MRS) Method—The MRS method defines a general approach to the representation of numerical data for data with positional significance. Decimal numbers are the most common example of numerical data with positional significance, and use a positional notation where digits are understood to be in the ones column, the tens column, the hundreds column, etc. The significance of a decimal number is understood to be its order of magnitude, and that is determined directly by the position of the highest-order non-zero digit. The MRS method takes advantage of positional significance to provide a compact representation of the significance of a numerical datum. The case of a binary series representation provides a particularly useful characteristic in that the highest-order term in the binary series, taken by itself, is greater than the sum of all other terms in the series. Thus knowledge of the highest-order term in the binary series representation guarantees that the MRS representation of the datum is bounded from below to within a factor of two. The binary series has the additional advantage that there is no ambiguity in the value of any non-zero symbol.

In order to apply the MRS method to other than binary numbers, it is necessary to first know the type of numbers and set of symbols being used. For example, with decimal integers this involves knowing the set of decimal integer symbols {0, 1, 2, . . . , 9}, along with the number of columns being considered and their position relative to the decimal point separating the whole part from the fractional part of the number. The MRS decimal representation would then code the location (column number) of the highest-order non-zero digit as a scale header. The precision packet would begin with the specific decimal value of the highest-order non-zero-digit, and then follow in order with the balance of the digits. The MRS representation would be guaranteed to bound the datum from below to within an order of magnitude.

The generalization to other numerical data types hinges on the positional significance of the underlying data representation. Both decimal and binary integers are examples of power series representations that are natural candidates for positional notation. Other series with known structure can be represented using the MRS method, but the utility of the method is clearly limited in cases where the positional significance is low or lacking.

The MRS method can also be generalized to the case of non-numerical data. In that case, the non-numerical symbols are first converted to an equivalent numerical code such as those for the ASCII and Unicode character sets, and the numerical codes are then represented using the MRS method.

2) Data Thinning—The decimal equivalent of a given length binary word and vice versa is readily calculable using equation (1). These are shown in Table VIII for various cases of interest. The equivalence is important to understand in sensibly representing data and the results of calculations relative to the number of significant figures. The most precisely measurable quantity is time/frequency with a relative precision of about 15 significant figures achieved by the best national standards laboratories. Other quantities are measured with far less precision, and many practical measurements are made at the level of two to three significant figures. In consequence, conventional fixed length binary representations are substantially inefficient in representing data that have a limited number of significant figures. The MRS representation can be significantly smaller than the conventional binary representation, particularly for large binary word lengths and small numbers of significant figures.

As an example, consider encoding the data stream generated by a high dynamic range measurement system using a 64-bit A/D converter. The 64-bit dynamic range of the A/D is equivalent to a 19 decimal digit data field. While the data may take any value within the dynamic range of the A/D, measurement noise and other processes will limit the accuracy and precision of the reported value. As an arbitrary example, consider the case of data having an accuracy and precision of one percent, in which case only 2 of the 19 decimal figures are significant. The data could be represented with as few as 7 bits under the proper representation format by leveraging its explicit and implicit a priori information. With slightly lesser efficiency, the 64-bit conventional binary integer data can be represented exactly using a fixed MRS(7) representation requiring 13 symbols. Because MRS includes precision within its basic design, that precision is carried forward and provided as a feature of the data transferred to MRS format.

TABLE VIII
Binary Word Length Required to Represent a
Given Number of Decimal Digits

| Number of Decimal | Required Binary Word |
|---|---|
| Digits Fully Represented | Length (bits) |
| 1 | 4 |
| 2 | 7 |
| 3 | 10 |
| 4 | 14 |
| 5 | 17 |
| 6 | 20 |
| 7 | 24 |
| 8 | 27 |
| 9 | 30 |
| 10 | 34 |
| 11 | 37 |
| 12 | 40 |
| 13 | 44 |
| 14 | 47 |
| 15 | 50 |
| 16 | 54 |
| 17 | 57 |
| 18 | 60 |
| 19 | 64 |
| 20 | 67 |

Note that the MRS approach in separating the scale header and additional precision packet provides a simple scheme for data thinning exclusively by truncation of the additional precision packet. Data thinning based on retaining only the significant figures, or equivalently significant bits, is accomplished simply by setting to zero all bits of the additional precision packet that represent values smaller than the specified relative precision. This type of data thinning can be performed independent of and without regard to the particular values of the scale header data, or as a specified function of the particular values of the scale header data. The thinning can be done both for measured and reference data, and for the results of numerical analyses as determined by the mathematical operations performed.

3) Data Compression Properties of the MRS Representation—The MRS method provides a number of options for reducing the number of symbols required to encode numerical data via data compression and data thinning. Data compression using MRS can be obtained in several ways, including the following:

Original data→MRS representation of the data→entropy encoding of the MRS representation

Original data→transform encoding→MRS representation of the transform coefficients→entropy encoding of the MRS representation

Original data→MRS representation of the data→transform encoding of the MRS representation→entropy encoding of the transform coefficients

Some important properties with respect to data compression are as follows.

a) Compression as a by-product of MRS structure. In any data representation, knowledge of the data structure provides explicit a priori knowledge that reduces the number of bits to be stored or transmitted. In the case of the MRS method applied to binary data, the a priori knowledge includes that the first non-zero symbol is a one. The location of that symbol must be specified, but not its value. Thus the explicit a priori structural information reduces by one the number of symbols that must be stored or transmitted to represent the full precision of a given datum.

The MRS representation provides for tracking of the most precise ‘true’ data bit. Consequently, interpolation for increased accuracy and precision is always available to the user of the data at the time of use, with no cost in storage and transmission. The caveat on the use of interpolation is, of course, that it is valid only on a statistical basis and is therefore only justified for data of a corresponding statistical nature.

Finally, the location of the highest-order non-zero bit coded in the MRS scale header provides implicit information on the maximum length of the corresponding precision packet, and that leads to a simple approach to using variable-length data structures for a more compact representation.

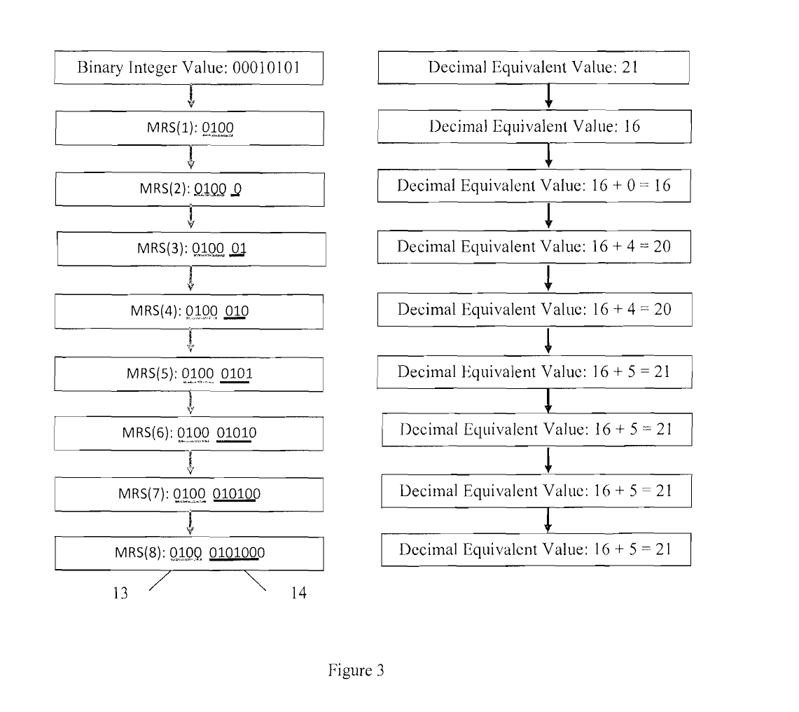

b) Compression via adjusted precision and data thinning. The MRS method provides a simple means to adjust the relative precision of the data representation by truncating the length of the precision packet appended to the scale header. The truncation length and resultant precision can be managed based on any suitable criterion established by user requirements for accuracy and precision as traded-off against the size of the representation. Compression via adjusted precision is illustrated in FIG. 3 using the previous example of the decimal integer “21” represented first as a binary integer, then using MRS representations of increasing precision from the coarsest to the finest (most exact) representation.

c) MRS and compression metrics. Even the least precise MRS representation provides an exact representation of the most significant term of the underlying series representation of the true data. While the mathematics have yet to be formalized, we anticipate excellent correlation coefficients and other similarity measures between the MRS representation and the ‘true’ data in all cases, including for limited precision under MRS(P). The reason is simple: the MRS representation is simply an alternate but exact representation of the same series expansion. The binary series expansion adds precision in order of significance and can never differ from the ‘true’ value by more than a factor of two, and that limiting maximum difference will follow through in the correlation coefficient or other similarity measures. We thus anticipate a correlation coefficient of 0.5 or more under normal circumstances.

A significant corollary arises in arrays of data such as the array of pixel intensities in a digital image. Since every individual datum is accurately represented to within a factor of two as bounded from below, the relative ratio between any two data points is always correct to within a factor from a maximum of two times larger to one half times smaller at the minimum. It is simply impossible with a binary implementation of MRS to even begin to approach order of magnitude errors in either the absolute data or its relative variations across a data array.

d) Joint use of MRS and transform or other compression approaches. Known techniques for data compression include a variety of transforms on and component decompositions of arrays of data represented as matrices. There is no apparent fundamental incompatibility between MRS and the use of transforms and other techniques as applied to data compression. However, there may be practical issues that will lead to a preferred order of operations when joining MRS with other techniques.

Applications and Considerations in Productization:

The MRS method is directly applicable to the representation of real integers through use of a binary series expansion. The method is readily extensible to complex and non-integer numerical data through obvious extensions of the MRS data structure and its explicit a priori information. The MRS method is further extensible to the representation of non-numerical character data through the use of numerical codes as designations for the character set(s) of interest, such as the ASCII and Unicode character sets.

The first usage of the MRS method has been in the compression of real valued synthetic aperture radar (SAR) imagery represented as a two dimensional array of integer pixel intensities with good results obtained. An extension to complex SAR imagery is being developed by the MacB ATG for evaluation. MRS experimentation using a variety of publicly available color and grayscale images including medical images is ongoing, with mixed results. Additional work on acoustic and other data types is also in progress. To date, there does not appear to be any substantial limitation to the potential application space for the MRS method. Additional applications have been proposed in hyperspectral imagery, RF signals, and even financial data.

The MRS method yields at least three significant advantages for image compression, storage, and transmission:

1) The MRS method in and of itself does not use a transform or other complicated mathematics to produce the MRS representation. The MRS method executes very quickly since the representation is formed with only a small number of operations required to find the location of the highest-order non-zero bit and encode its location, followed by appending the additional precision packet and any zero padding to the right.

2) The structure of the MRS scale header paired with a corresponding additional precision packet eliminates the need to create, store, and transmit separate “low” and “high” resolution images. The lowest possible resolution MRS(1) image is just the scale header, with the characteristics as noted that all pixel intensities are within a factor of two of their true values, bounded from below, and the ratio of any two pixel intensities is correct to within a factor of two larger or smaller by one half Adding precision is accomplished by adding additional precision bits to the MRS representation. For images stored as two dimensional intensity arrays, the data are conveniently handled as bit planes. The MRS(1) image can be increased in precision up to the MRS(N) limit (full fidelity) by over-writing one bit plane at a time, as needed. The MRS symbols on-hand are always correct symbols, and the precision of the image is refined without any need to recalculate the image.

3) Especially for large images, the MRS structure enables the transmission and display of the MRS(1) minimum precision image for use as a preview or screening image, and the rapid back-fill with increased precision in designated areas of the image. The additional precision is simply added into the existing data fields by over-writing the additional precision bits for a particular data element. It is a simple matter to designate a region and request only the additional precision packets for that specified region. Thus any number of regions in the MRS(1) screening image can be designated for increased precision without requiring any calculations. All that is required is to read the data, and over-write the additional precision bits as the data are re-stored. Further, that operation can be performed incrementally as MRS(1) to MRS(2), then to MRS(3), etc., up to MRS(N), or directly to MRS(N) or any other precision depending upon the user's particular interests.

While particular embodiments have been chosen to illustrate the invention, it will be understood by those skilled in the art that various changes and modifications can be made therein without departing from the scope of the invention as defined in the appended claims.

What is claimed is:

1. A method for numerically encoding and representing data, the method comprising:
providing a representation of data;
separating the representation into a scale header and an additional precision packet, wherein separating the representation includes:
identifying the location of the highest-order non-zero bit;
encoding the location of the highest-order non-zero bit to form the scale header; and
encoding the balance of the bits following the highest-order non-zero bit, or a truncated set of these bits, to form the precision packet; and
composing a matched representation space (MRS) representation as the paired data structures of the scale header and its corresponding precision packet.

2. The method of claim 1 wherein encoding the location of the highest-order non-zero bit includes one of: coding the total number of significant elements, coding the number of leading zeros, or coding the location as number of columns from the left in an N-bit format.

3. The method of claim 1 wherein the precision packet represents additional precision in the representation.

4. The method of claim 1 wherein the MRS representation includes a binary word.

5. The method of claim 1 wherein composing the MRS representation includes using one of: a full precision MRS representation with fixed length data structures, a full precision MRS representation with variable length data structures, an adjusted precision MRS representation with fixed length data structures, or an adjusted precision MRS representation with variable length data structures.

6. The method of claim 1 wherein the MRS representation is used to represent one of: real integers using a binary series expansion, complex and non-integer numerical data, and non-numerical character data using numerical codes as designations for the character set(s) of interest.

7. The method of claim 6 wherein the numerical codes include ASCII and Unicode character sets.

8. The method of claim 1 further comprising using the MRS representation for compressing one of: real valued synthetic aperture radar (SAR) imagery represented as a two dimensional array of integer pixel intensities, color and grayscale medical imagery data, and acoustic data.

9. The method of claim 1 wherein the MRS representation is used for transmitting and displaying an MRS minimum precision image for use as a preview image, the method further comprising:
designating a region of an image associated with a data element;
back-filling designated region of the image with increased precision by requesting only the precision packets for the designated region; and
over-writing the additional precision bits for the data element as the data are re-stored.

10. A method for representing and encoding numerical data, the method comprising:
decomposing numerical data into a weighted sum of constituent terms;
determining an order of potential significance among the constituent terms;
determining a first representation of the numerical data as the sequence of weights in a predetermined order;
determining a second representation of the numerical data that separates the first representation into a scale header and an additional precision packet, wherein separating the first representation includes:
identifying the location of the term having jointly the highest potential significance among the constituent terms and a non-zero weighting coefficient;
encoding the location, in the determined sequence of weights, of the term having jointly the highest potential significance among the constituent terms and a non-zero weighting coefficient as a scale header; and
encoding the balance of the weights associated with terms of lesser potential significance, or a truncated set of these weights, as an additional precision packet; and
composing a matched representation space (MRS) representation as the paired data structures of a scale header and its corresponding additional precision packet.

11. The method of claim 10 wherein decomposing the numerical data into a weighted sum of constituent terms includes decomposing the numerical data into a weighted sum of terms forming a regular series.

12. The method of claim 11 wherein the regular series is a power series.

13. The method of claim 12 wherein the power series is a decimal (base 10) series.

14. The method of claim 12 wherein the power series is a hexadecimal (base 16) series.

15. The method of claim 12 wherein the power series is an octal (base 8) series.

16. The method of claim 12 wherein the power series is a binary (base 2) series.

17. The method of claim 10 wherein determining an order of potential significance among the constituent terms is determined in accordance with the indexed exponent in a power series expansion.

18. The method of claim 10 wherein determining a first representation of the numerical data includes ordering the sequence from highest potential significance to least potential significance.

19. The method of claim 10 wherein determining a first representation of the numerical data includes ordering the sequence from least potential significance to highest potential significance.

20. The method of claim 10 wherein determining a first representation of the numerical data includes ordering the sequence according to a likelihood of a coefficient being non-zero within a set of numerical data.

21. The method of claim 10 With explicit prior agreement as to the least significant term and its location, coding the total number of significant elements,

22. The method of claim 10 wherein encoding the location of the term having jointly the highest potential significance includes, with explicit prior agreement as to the least significant term, and the sequence ordered in order of decreasing importance, coding the location as number of columns from the right.

23. The method of claim 10 wherein encoding the location of the term having jointly the highest potential significance includes, with explicit prior agreement as to the total number of elements under consideration, and the sequence ordered in order of decreasing importance, coding the number of leading zeros, or coding the location as number of columns from the left.

24. The method of claim 10 wherein encoding the location of the term having jointly the highest potential significance includes, with explicit prior agreement as to the least significant term, and the sequence ordered in order of increasing importance, coding the location as number of columns from the left.

25. The method of claim 10 wherein encoding the location of the term having jointly the highest potential significance includes, with explicit prior agreement as to the total number of elements under consideration, and the sequence ordered in order of increasing importance, coding the number of trailing zeros, or coding the location as number of columns from the right.

26. The method of claim 10 wherein encoding the balance of weights includes placing the weights into the additional precision packet according to an agreed to ordering.

27. The method of claim 10 wherein encoding the balance of weights includes placing the weights in decreasing order of importance.

28. The method of claim 10 wherein encoding the balance of weights includes placing the weights in increasing order of importance.

29. The method of claim 10 wherein encoding the balance of weights includes truncating the balance according to one or more predetermined truncation rules.

30. The method of claim 29 wherein the one or more predetermined truncation rules remove weights, in order, from the potentially least significant term to the potentially most significant term represented in the additional precision packet.

31. The method of claim 29 wherein the one or more predetermined truncation rules limit the truncation in order to maintain an agreed absolute accuracy or precision in the numerical representation.

32. The method of claim 29 wherein the one or more predetermined truncation rules limit the truncation in order to maintain an agreed relative accuracy or precision in the numerical representation.

33. The method of claim 29 wherein the one or more predetermined truncation rules limit the truncation in order to maintain agreed absolute and relative accuracy or precision in the numerical representation.

34. The method of claim 29 wherein the one or more predetermined truncation rules are configured to adjust the degree of truncation based upon the magnitude of the numerical data.

35. The method of claim 10 wherein encoding the balance of weights includes conditioning the variability in the length or size of the additional precision packet based on an aspect of the data.

36. The method of claim 10 wherein composing the MRS representation includes composing a MRS representation where the paired data structures, taken together, represent a single numerical datum.

37. The method of claim 10 wherein composing the MRS representation includes composing a MRS representation where the paired data structures, taken together, represent multiple numerical data.

38. The method of claim 10 wherein composing the MRS representation includes composing a MRS representation where the paired data structures, taken together, represent multiple numerical data and the paired data structures are stored, transmitted, or processed on an element-by-element interleaved scale header—additional precision packet basis.

39. The method of claim 10 wherein composing the MRS representation includes composing a MRS representation where the paired data structures, taken together, represent multiple numerical data and the paired data structures are stored, transmitted, or processed as separate scale header and additional precision packet structures.

40. The method of claim 10 further comprising packing the MRS method data in a more compact format using entropy encoding techniques.

41. The method of claim 40 wherein the entropy encoding is applied differently to the separate scale header and additional precision packet data structures.

42. The method of claim 10 further comprising converting the MRS representation into a conventional representation and applying a statistical interpolation.
